(19) United States
(12) Patent Application Publication
(10) Pub. No.: US 2026/0354273 A1
(43) Pub. Date: Nov. 5, 2026

(54) PACKAGES WITH DEEP BOND PADS AND METHOD FORMING SAME

(71) Applicant: Taiwan Semiconductor Manufacturing Co., Ltd., Hsinchu (TW)

(72) Inventors: Chen-Hua Yu, Hsinchu (TW); Shih-Chang Ku, Taipei City (TW); Chien-Yuan Huang, Hsinchu (TW); Chuei-Tang Wang, Taichung City (TW); Sey-Ping Sun, Hsinchu (TW)

(21) Appl. No.: 19/734,310

(22) Filed: Jul. 8, 2026

Related U.S. Application Data
(62) Division of application No. 17/651,335, filed on Feb. 16, 2022.
(60) Provisional application No. 63/289,664, filed on Dec. 15, 2021.

(51) Int. Cl. H10W 90/00; H10W 72/00; H10W 72/90; H10W 80/00

(52) U.S. Cl. CPC H10W 90/00; H10W 72/01; H10W 72/019; H10W 72/823; H10W 72/90; H10W 72/921; H10W 72/926; H10W 80/312; H10W 80/327; H10W 80/721; H10W 90/792

(57) ABSTRACT

A method includes forming a first dielectric layer on a first wafer, and forming a first bond pad penetrating through the first dielectric layer. The first wafer includes a first semiconductor substrate, and the first bond pad is in contact with a first surface of the first semiconductor substrate. The method further includes forming a second dielectric layer on a second wafer and forming a second bond pad extending into the second dielectric layer. The second wafer includes a second semiconductor substrate. The first wafer is sawed into a plurality of dies, with the first bond pad being in a first die in the plurality of dies. The first bond pad is bonded to the second bond pad.

### PRIORITY CLAIM AND CROSS-REFERENCE

This application is a divisional of U.S. Patent Application No. 17/651,335, entitled “Packages With Deep Bond Pads and Method Forming Same,” filed on Feb. 16, 2022, which claims the benefit of the following provisionally filed U.S. Patent application: Application No. 63/289,664, filed on Dec. 15, 2021, and entitled “Semiconductor Structure and Manufacturing Method Thereof,” which applications are hereby incorporated herein by reference.

### BACKGROUND

Hybrid bonding is a common bonding scheme for bonding two package components such as wafers and dies to each other. With the hybrid bonding, high bonding strength can be achieved without increasing the cost for forming the package components that are bonded.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9 illustrate the cross-sectional views of intermediate stages in the formation of a die in accordance with some embodiments.

FIGS. 10-14 illustrate the cross-sectional views of some dies formed using the processes shown in FIGS. 1-9 in accordance with some embodiments.

FIG. 15 illustrates a die stack formed through hybrid bonding in accordance with some embodiments.

FIGS. 16 and 17 illustrate the bonded dies in accordance with some embodiments.

FIG. 18-21 illustrate the top views of some bond pads in accordance with some embodiments.

FIG. 22 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Device dies including deep bond pads and the method of forming the same are provided. Packages including bonded device dies are illustrated. The deep bond pads may extend to a semiconductor substrate of the corresponding device die. With the deep bond pads being formed, the heat dissipation of the resulting package is improved, and the bonding is more reliable. The deep bond pads may be used to achieve hybrid bonding in combination with the bonding of dielectric layers. The deep bond pads may also be used in combination with shallow bond pads and/or active metal pads, Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

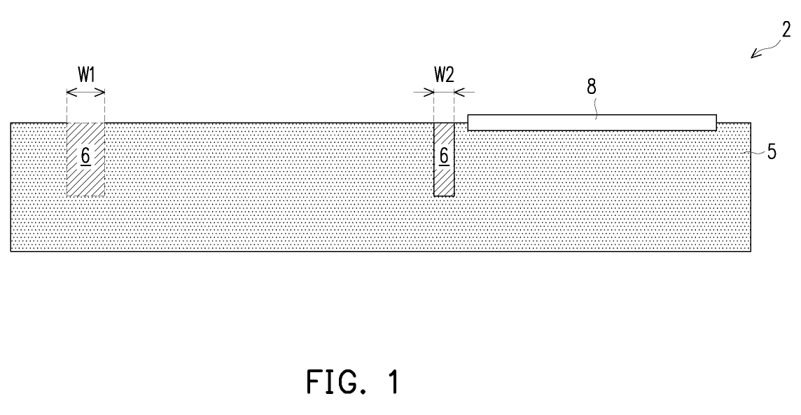

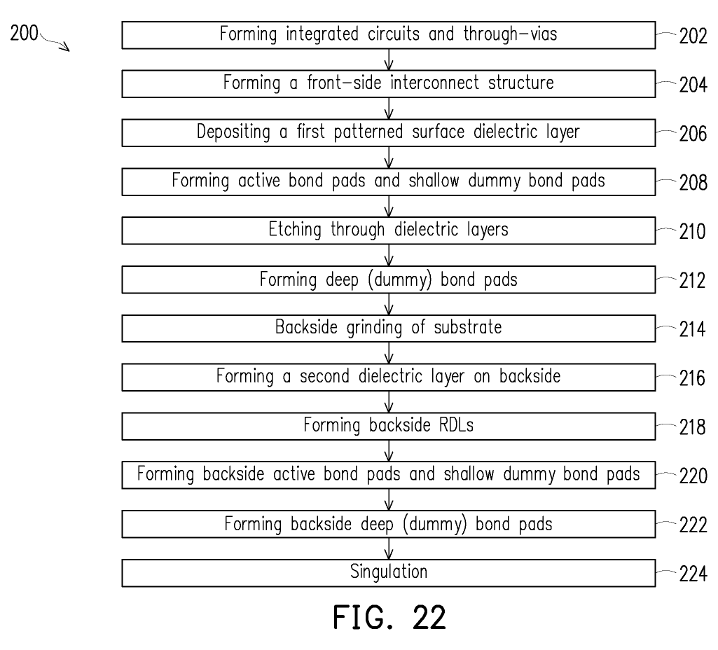

FIGS. 1-9 illustrate the cross-sectional views of intermediate stages in the formation of a wafer and dies in accordance with some embodiments of the present disclosure. The corresponding processes are also reflected schematically in the process flow 200 as shown in FIG. 22.

FIG. 1 illustrates the cross-sectional view in the formation of integrated circuits and through-vias in wafer 2. The respective process is illustrated as process 202 in the process flow 200 as shown in FIG. 22. In accordance with some embodiments of the present disclosure, wafer 2 is a device wafer including active devices such as transistors and/or diodes, and/or passive devices such as capacitors, inductors, resistors, or the like. In accordance with alternative embodiments, wafer 2 is a dummy wafer free from active devices. Device wafer 2 may include a plurality of identical chips 4 therein, with one of chips 4 illustrated. Chips 4 are alternatively referred to as (device) dies hereinafter.

Dies 4 may be selected from various types of device dies. In accordance with some embodiments of the present disclosure, device dies 4 are logic dies, which may be Central Processing Unit (CPU) dies, Graphics Processing Unit (GPU) dies, Micro Control Unit (MCU) dies, BaseBand (BB) dies, Application processor (AP) dies, or the like. In accordance with alternative embodiments, dies 4 are memory dies, which may be Static Random Access Memory (SRAM) dies, Dynamic Random Access Memory (DRAM) dies, Resistive Random Access Memory (RRAM) dies, or the like. In accordance with yet alternative embodiments, dies 4 are analog dies or dummy dies. When being dummy dies, dies 4 are free from active devices such as transistors and diodes, and/or passive devices such as capacitors, resistors, inductors, and the like.

In accordance with some embodiments of the present disclosure, wafer 2 includes semiconductor substrate 5. Semiconductor substrate 5 may be formed of crystalline silicon, crystalline germanium, crystalline silicon germanium, or a III-V compound semiconductor such as GaAsP, AlInAs, AlGaAs, GaInAs, GaInP, GaInAsP, or the like. Semiconductor substrate 5 may also be a bulk silicon substrate or a Silicon-On-Insulator (SOI) substrate. Shallow Trench Isolation (STI) regions (not shown) may be formed in semiconductor substrate 5 to isolate the active regions in semiconductor substrate 5.

In accordance with some embodiments, through-vias 6 (also sometimes referred to as through-silicon vias or through-semiconductor vias) are formed to extend into semiconductor substrate 5. Through-vias 6 may be formed of or comprise a metallic material such as copper, nickel, tungsten, or the like. Isolation layers (not shown) are formed encircling through-vias 6 and to electrically isolate through-vias 6 from semiconductor substrate 5. Through-vias 6 are formed to extend to an intermediate level between a top surface and a bottom surface of semiconductor substrate 5. One of the through-vias 6 is shown as being dashed to indicate that it may or may not be formed. Through-vias 6 may have different sizes. For example, widths (or diameter) W1 of some through-vias 6 (which may be used for thermal conducting) are greater than width W2 of some other through-vias 6 (which may be used for routing electrical signals). In accordance with alternative embodiments, device dies 4 are free from through-vias therein.

In accordance with some embodiments of the present disclosure, device dies 4 are active dies including integrated circuit devices 8, which are formed on the top surface of semiconductor substrate 5. Example integrated circuit devices 8 may include active devices such as Complementary Metal-Oxide Semiconductor (CMOS) transistors and diodes, and passive devices such as resistors, capacitors, inductors, and/or the like. The details of integrated circuit devices 8 are not illustrated herein. In accordance with alternative embodiments, device dies 4 are dummy dies, which are free from active devices and passive devices therein.

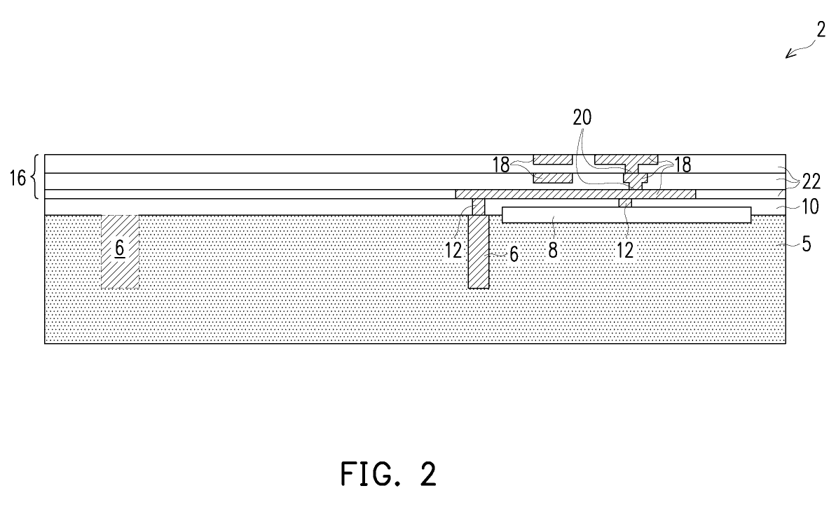

FIG. 2 illustrates the formation of a front-side interconnect structure 16. The respective process is illustrated as process 204 in the process flow 200 as shown in FIG. 22. Inter-Layer Dielectric (ILD) 10 is formed over semiconductor substrate 5 and fills the space between the gate stacks of transistors (not shown) in integrated circuit devices 8. In accordance with some example embodiments, ILD 10 is formed of silicon oxide, Phospho Silicate Glass (PSG), Boro Silicate Glass (BSG), Boron-Doped Phospho Silicate Glass (BPSG), Fluorine-Doped Silicate Glass (FSG), or the like. ILD 10 may be formed using spin coating, Flowable Chemical Vapor Deposition (FCVD), Chemical Vapor Deposition (CVD), Plasma Enhanced Chemical Vapor Deposition (PECVD), Low Pressure Chemical Vapor Deposition (LPCVD), or the like.

Contact plugs 12 are formed in ILD 10, and are used to electrically connect integrated circuit devices 8 and through-vias 6 to overlying metal lines and vias. In accordance with some embodiments of the present disclosure, contact plugs 12 are formed of a conductive material selected from tungsten, aluminum, copper, titanium, tantalum, titanium nitride, tantalum nitride, alloys thereof, and/or multi-layers thereof. The formation of contact plugs 12 may include forming contact openings in ILD 10, filling a conductive material(s) into the contact openings, and performing a planarization (such as a Chemical Mechanical Polish (CMP) process) to level the top surfaces of contact plugs 12 with the top surface of ILD 10.

Over ILD 10 and contact plugs 12, interconnect structure 16 is formed. Interconnect structure 16 includes dielectric layers 22, metal lines (and pads) 18, and vias 20 in dielectric layers 22. Dielectric layers 22 are alternatively referred to as Inter-Metal Dielectric (IMD) layers 22 hereinafter. In accordance with some embodiments of the present disclosure, some or all of dielectric layers 22 are formed of low-k dielectric materials having dielectric constant values (k-values) lower than about 3.0 or about 2.5. Dielectric layers 22 may be formed of a carbon-containing low-k dielectric material, Hydrogen SilsesQuioxane (HSQ), MethylSilsesQuioxane (MSQ), or the like. In accordance with some embodiments of the present disclosure, the formation of dielectric layers 22 includes depositing a porogen-containing dielectric material, and then performing a curing process to drive out the porogen, and hence the remaining dielectric layers 22 is porous. In accordance with alternative embodiments of the present disclosure, some or all of dielectric layers 22 are formed of non-low-k dielectric materials such as silicon oxide, silicon carbide (SiC), silicon carbo-nitride (SiCN), silicon oxy-carbo-nitride (SiOCN), or the like. Etch stop layers (not shown), which may be formed of silicon oxynitride, aluminum oxide, aluminum nitride, or the like, or combinations thereof, may be formed between IMD layers 22, and are not shown for simplicity.

Metal lines 18 and vias 20 are formed in dielectric layers 22. The metal lines 18 at a same level are collectively referred to as a metal layer hereinafter. In accordance with some embodiments of the present disclosure, interconnect structure 16 includes a plurality of metal layers that are interconnected through vias 20. Metal lines 18 and vias 20 may be formed of copper or copper alloys, and they can also be formed of other metals. The formation process may include single damascene and dual damascene processes. In an example single damascene process, a trench is first formed in one of dielectric layers 22, followed by filling the trench with a conductive material. A planarization process such as a CMP process is then performed to remove the excess portions of the conductive material higher than the top surface of the IMD layer, leaving a metal line in the trench. In a dual damascene process, both a trench and a via opening are formed in an IMD layer, with the via opening underlying and connected to the trench. The conductive material is then filled into the trench and the via opening to form a metal line and a via, respectively. The conductive material may include a diffusion barrier layer and a copper-containing metallic material over the diffusion barrier layer. The diffusion barrier layer may include titanium, titanium nitride, tantalum, tantalum nitride, or the like.

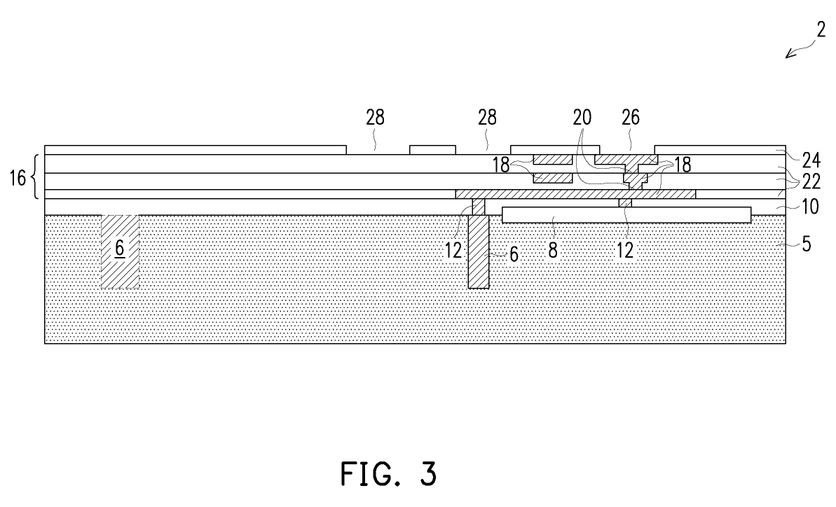

Referring to FIG. 3, surface dielectric layer 24 is deposited in accordance with some embodiments of the present disclosure. The respective process is illustrated as process 206 in the process flow 200 as shown in FIG. 22. Surface dielectric layer 24 is formed of a non-low-k dielectric material, and may be in physical contact with the underlying dielectric layer 22, or separated from dielectric layer 22 by other layers such as an etch stop layer. Surface dielectric layer 24 may be a silicon-oxide-based dielectric material comprising silicon and another element(s) including oxygen, nitrogen, carbon, or the like, or combinations thereof. For example, surface dielectric layer 24 may be formed of or comprise silicon oxide, silicon oxynitride (SiON), silicon nitride (SiN), silicon oxy-nitride (SiON), silicon oxy-carbo-nitride (SiOCN), silicon carbon-nitride (SiCN), silicon oxy-carbide (SiOC), silicon carbide (SiC), or the like.

Openings 26 and 28 are formed in surface dielectric layer 24 through etching processes. In the formation of openings 26, the metal pads in metal lines/pads 18 in the top metal layer are used as the etch stop layer, and the metal pads 18 are revealed. In the formation of openings 28, an underlying dielectric layer is used as the etch stop layer, and is exposed to openings 28. Although not shown, openings 26 may include via openings and trenches over the via openings, which are used for forming dual damascene structures.

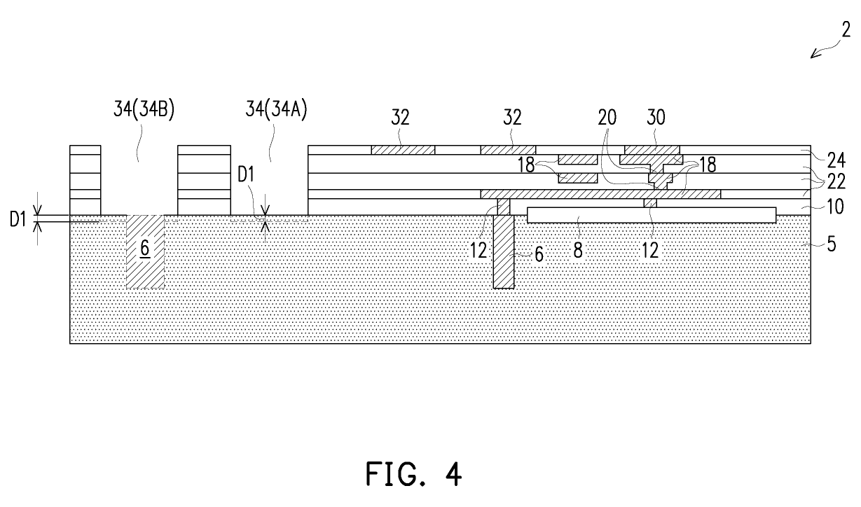

Referring to FIG. 4, active bond pads 30 and shallow bond pads 32 are formed. The respective process is illustrated as process 208 in the process flow 200 as shown in FIG. 22. Shallow bond pads 32 are dummy bond pads that are electrically floating in the final package. The formation process may include depositing a conformal barrier layer (using a conductive material such as TiN, TaN, Ti, Ta, or the like), depositing a metallic material such as copper, tungsten, cobalt, or the like, and preforming a planarization process to remove excess materials.

FIG. 4 further illustrates the formation of openings 34 (including openings 34A and 34B) through a plurality of etching processes. The respective process is illustrated as process 210 in the process flow 200 as shown in FIG. 22. The plurality of etching processes may adopt different etching gases in response to different materials of dielectric layers 22, ILD 10, and the etch stop layers. The top surface of semiconductor substrate 5 is exposed to opening 34A. The top surface of semiconductor substrate 5 and the top surface of one of through-vias 6 (if formed) are exposed to opening 34B. In accordance with some embodiments, openings 34 have their bottom surfaces level with or substantially level with the top surface of semiconductor substrate 5. In accordance with alternative embodiments, openings 34 extend into semiconductor substrate 5 to form recesses having depth D1, which may be greater than about 10Å. Depth D1 may also be in the range between about 10Å and about 100Å. The dashed lines represent the corresponding bottoms and sidewalls of the recesses.

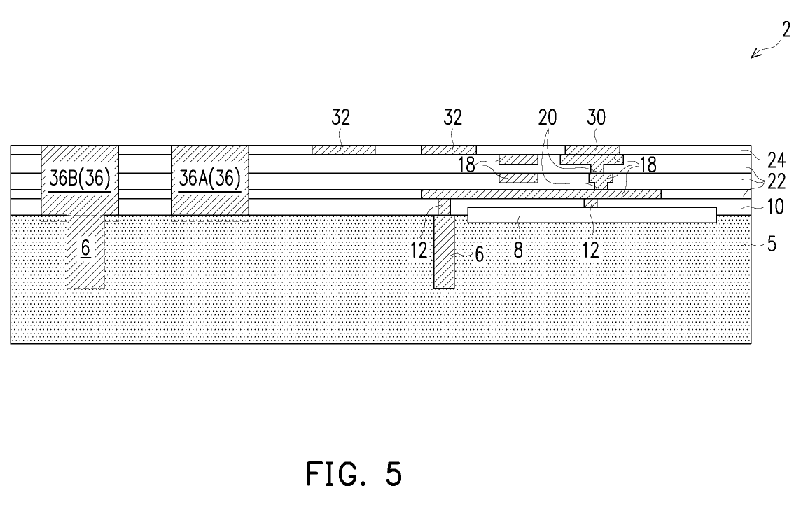

Referring to FIG. 5, deep bond pads 36 (including 36A and 36B) are formed. The respective process is illustrated as process 212 in the process flow 200 as shown in FIG. 22. The formation process may also include depositing a conformal barrier layer (such as TiN, TaN, Ti, Ta, or the like), depositing a metallic material such as copper, tungsten, cobalt, or the like, and preforming a planarization process to remove excess materials. The resulting deep bond pad 36A has its entire bottom surface contacting the top surface of semiconductor substrate 5. Furthermore, the sidewalls of deep bond pad 36A may not be connected to any other conductive features (such as metal features). Deep bond pad 36B, on the other hand, is electrically connected to the underlying through-via 6. It is appreciated that the corresponding through-via 6 is illustrated using dashed lines to indicate that it may or may not be formed. Deep bond pads 36 may have straight sidewalls extending from the top surface of dielectric layer 24 to the top surface of semiconductor substrate 5.

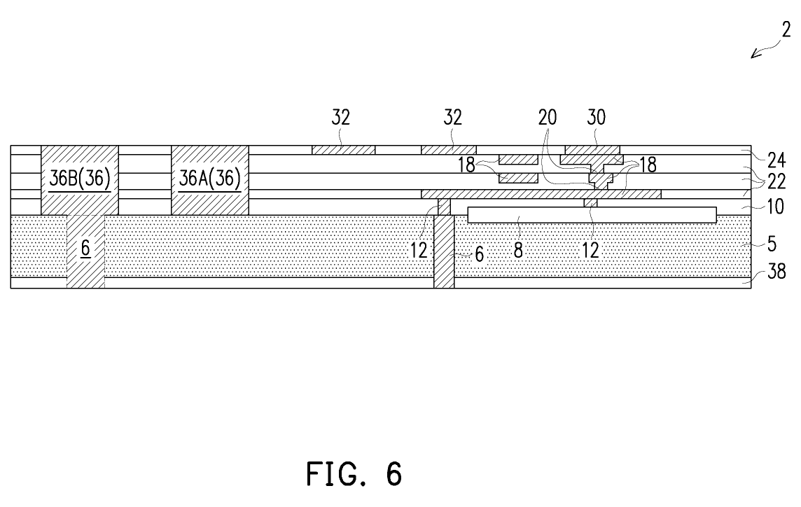

Next, as shown in FIG. 6, a backside grinding process is performed on the backside (the illustrated bottom side) of semiconductor substrate 5 to remove a portion of semiconductor substrate 5, until through-vias 6 are revealed. The respective process is illustrated as process 214 in the process flow 200 as shown in FIG. 22. Semiconductor substrate 5 is then recessed slightly (for example, through etching) from the backside, so that through-vias 6 protrude out of the back surface (the illustrated bottom surface) of semiconductor substrate 5.

In accordance with alternative embodiments, no through-vias 6 are formed, and the processes (as shown in FIGS. 6-9) performed on the backside of wafer 2 are skipped.

Next, as also shown in FIG. 6, dielectric layer 38 is deposited, followed by a CMP process or a mechanical grinding process to re-expose through-vias 6. The respective process is illustrated as process 216 in the process flow 200 as shown in FIG. 22. Through-vias 6 thus penetrate through dielectric layer 38 also. In accordance with some embodiments, dielectric layer 38 is formed of silicon oxide, silicon nitride, silicon oxynitride, silicon carbon-nitride, or the like.

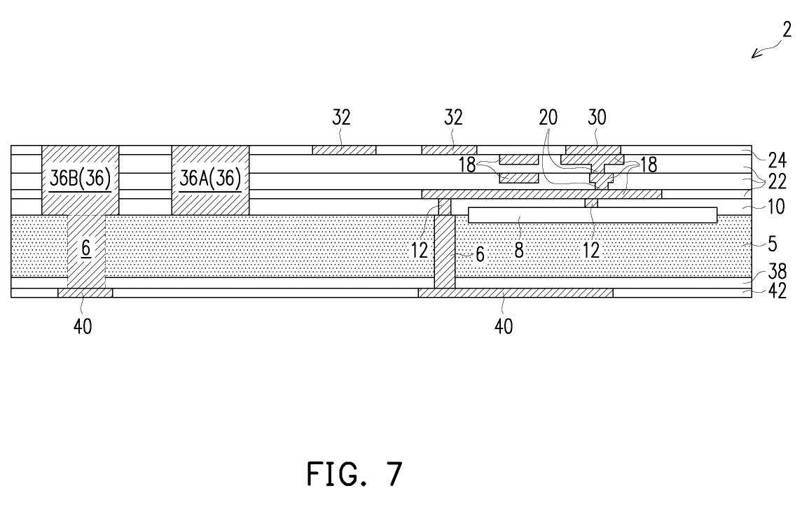

Referring to FIG. 7, backside Redistribution Lines (RDLs) 40 may be formed, which include pad portions contacting through-vias 6. The respective process is illustrated as process 218 in the process flow 200 as shown in FIG. 22. RDLs 40 may be formed of aluminum, copper, nickel, titanium, or the like in accordance with some embodiments. Dielectric layer 42 may be formed, with RDLs 40 extending into dielectric layer 42. Although one dielectric layer 42 and one layer of RDLs 40 are formed as an example, there may be a plurality of dielectric layers and a plurality of layers of RDLs formed, depending on the routing requirement.

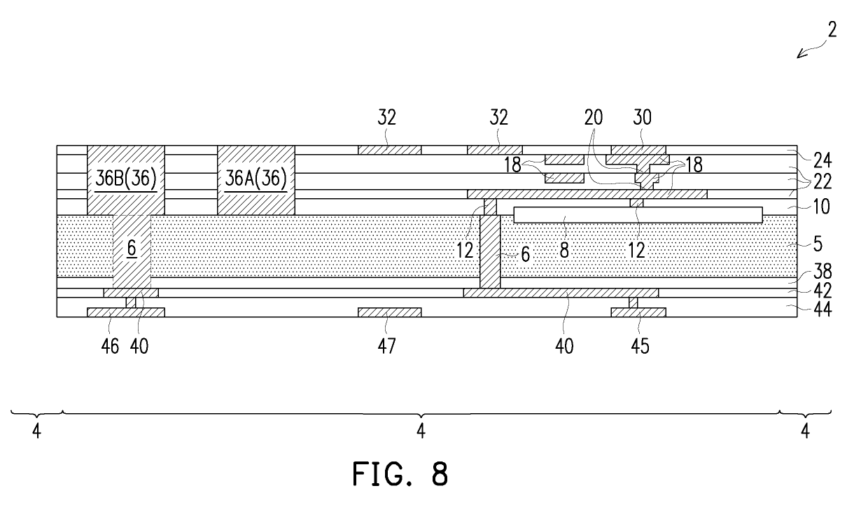

FIG. 8 further illustrates the formation of active bond pads 45, shallow bond pads 47, and bond pads 46. The respective process is illustrated as process 220 in the process flow 200 as shown in FIG. 22. Active bond pads 45 are electrically connected to through-vias 6, which are further connected to integrated circuits 8 and/or active bond pads 30. Bond pads 46 are electrically connected to through-vias 6 and deep bond pads 36B. Shallow bond pads 47 are dummy bond pads that are electrically floating in the final package, with each being fully encircled by dielectric materials. In accordance with some embodiments, bond pads 46 are formed of or comprise titanium nitride, copper, tungsten, or the like, multi-layers thereof, and/or alloys thereof.

In accordance with some embodiments, bond pads 46 are formed in surface dielectric layer 44, which may comprise or may be formed of silicon oxide, SiN, SiC, SiOC, SiON, SiOCN, or the like. The bottom surface of bond pads 46 may be coplanar with the bottom surface of surface dielectric layer 44.

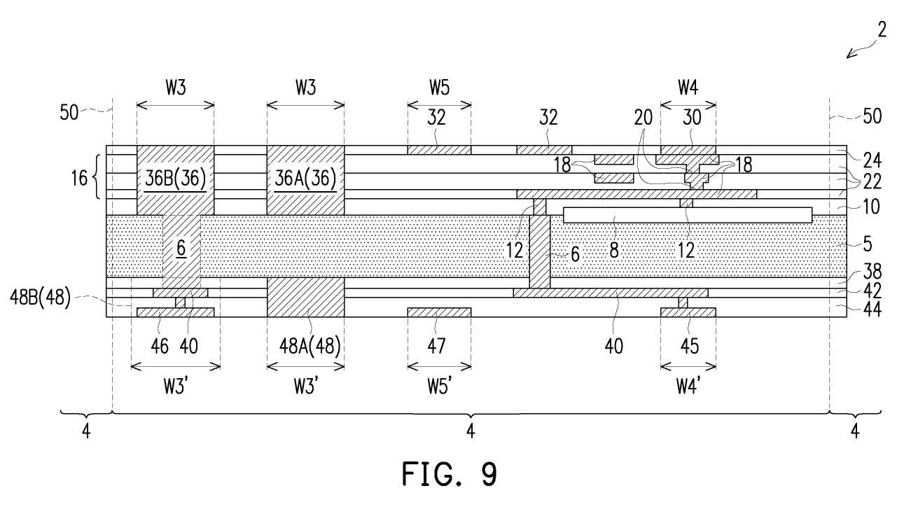

FIG. 9 illustrates the formation of deep bond pads 48A. The respective process is illustrated as process 222 in the process flow 200 as shown in FIG. 22. In accordance with some embodiments, the formation of deep bond pads 48A includes etching-through dielectric layers 38, 42, and 44 to form openings on the backside of semiconductor substrate 5, so that the back surface (the illustrated bottom surface) of semiconductor substrate 5 is exposed to the openings, filling the openings with conductive materials, and performing a planarization process. The conductive materials of deep bond pads 48A may be selected from the same group of candidate materials for forming deep bond pads 36A. In accordance with these embodiments, deep bond pads 48A may be thermally connected to deep bond pads 36A through semiconductor substrate 5 to form thermal conducting channels.

In accordance with alternative embodiments, instead of forming bond pads 46 and RDLs 40 to connect to through-via 6 and deep bond pad 36B, deep bond pad 48B, which is illustrated using dashed lines, is formed on the backside of semiconductor substrate. Deep bond pad 48B may be formed simultaneously as the formation of deep bond pad 48A. Deep bond pads 36B and 48B and the corresponding through-via 6 thus form thermal conducting channels.

In accordance with some embodiments, the lateral sizes W3 of deep bond pads 36 and lateral sizes W3’ of deep bond pads 48 are greater than the lateral sizes W4 of active bond pads 30 and the lateral sizes W4’ of active bond pads 45. Accordingly, the thermal conducting efficiency of the thermal conducting paths is improved, and at the same time more signal paths may be formed. Lateral sizes W3 and W3’ may also be equal to or greater than the lateral sizes W5 of shallow bond pads 32 and the lateral sizes W5’ of shallow bond pads 47.

In a subsequent process, wafer 2 may be singulated through a sawing process along scribe lines 50, and device dies 4 are separated from each other. The respective process is illustrated as process 224 in the process flow 200 as shown in FIG. 22.

The device dies 4 may include four types of bond pads including active bond pad 30, (dummy) shallow bond pads 32, deep bond pad 36A, and deep bond pad 36B in any combination, which means that in a die, one, two, three, or all four types of bond pads may be formed in a same side of device die 4 in any combination. These combinations of bond pads may be formed on the front side (alternatively referred to as active side), backside, or both of the front side and backside of semiconductor substrate 5. Throughout the description, the side of semiconductor substrate 5 having active integrated circuit 8 is referred to the active side or front side, and the opposite side is referred to the inactive side or backside. When formed on the backside, device dies 4 may include one, two, three or four types of active bond pads 45, shallow bond pads 47, bond pads 46, and deep bond pads 48 in any combination.

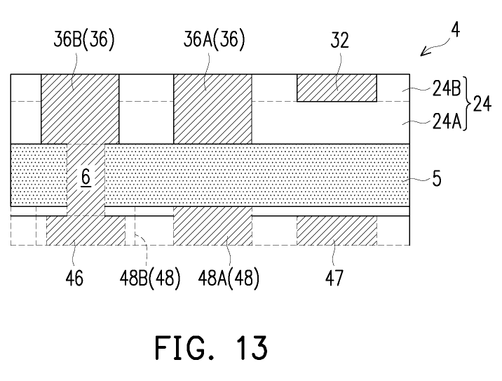

Furthermore, device dies 4 may include integrated circuits 8, which may include active devices, and may or may not include passive devices. The corresponding device dies 4 are active device dies. In accordance with alternative embodiments, device dies 4 include passive devices and are free from active devices. In accordance with yet alternative embodiments, device dies 4 are free from both of active devices and passive devices. In which case, device dies 4 are dummy dies. Some example dummy dies 4 are shown in FIGS. 13, 14, and 15.

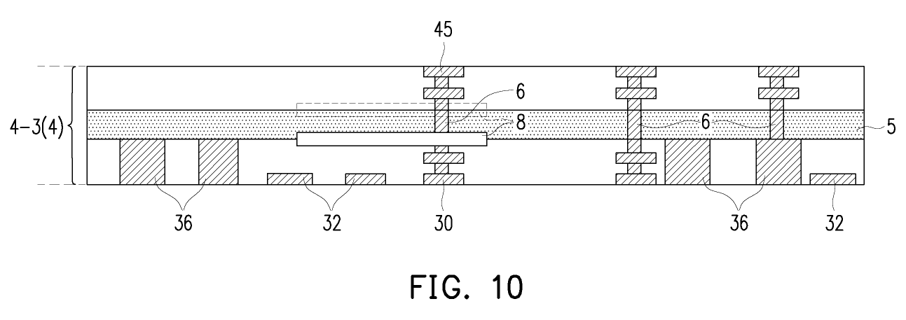

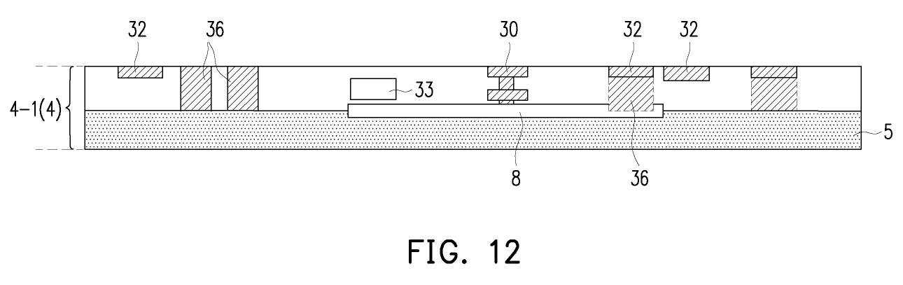

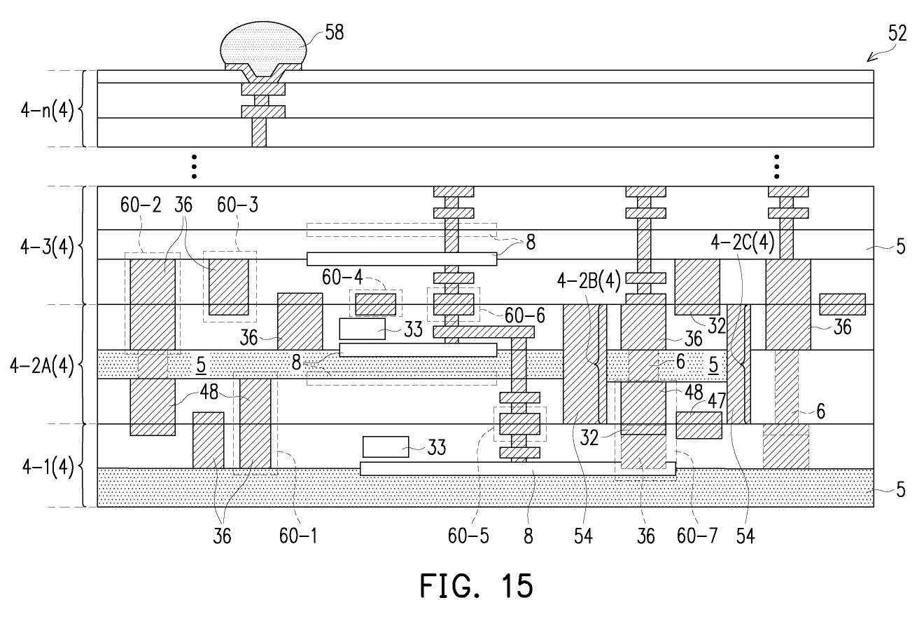

In some device dies 4, through-vias 6 are formed, and bond pads are formed on both of the front side and the backside of the respective device dies 4. The resulting device dies 4 are referred to as double-sided device dies, with some examples shown in FIGS. 10, 11, and 13-15. In some other device dies 4, no through-vias 6 are formed, and the processes (as shown in FIGS. 6 - 9) performed on the backside of wafer 2 are skipped. The resulting device dies 4 are single-sided, with example single-sided device dies 4 shown in FIGS. 12 and 15.

FIGS. 10-14 illustrate some example device dies 4, which may be formed using the processes as discussed referring to FIGS. 1-9. The example device dies 4 are stacked to form the package as shown in FIG. 15. The device dies 4 in accordance with these embodiments have different combinations of features, which are addressed above. It is appreciated that, as also aforementioned, any other combination may also be adopted to form different device dies, which are also in the scope of the present disclosure. The details (such as dielectric layers, metal lines, vias, RDLs, etc.) of the device dies in these figures are not shown, and the details may be found referring to the previously discussed embodiments.

FIG. 10 illustrates double-sided device die 4 (also denoted as 4-3) in accordance with some embodiments. The illustrated bottom side of the corresponding device die 4 may be the front side, and the respective integrated circuits 8 are at the position shown using solid lines. In accordance with alternative embodiments, the illustrated top side of the corresponding device dies 4 may be the front side, and the respective integrated circuits 8 are at the position shown using dashed lines.

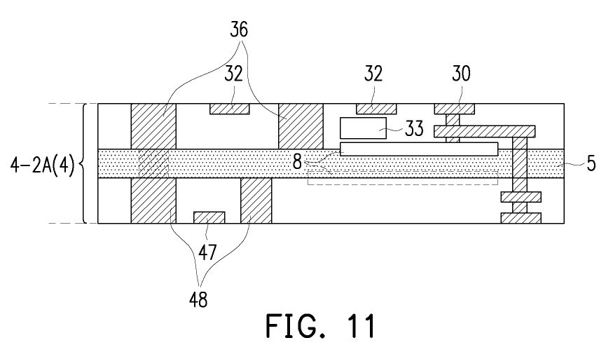

In FIG. 11, the illustrated top side of the corresponding device die 4 (also denoted as 4-2A) may be the front side, and a dashed box is also illustrated to show that the illustrated bottom side may instead be the front side of the respective device die 4. Passive devices 33 are also illustrated schematically.

FIG. 12 illustrates a single-sided device die 4 (also denoted as 4-1) in accordance with some embodiments. The deep bond pads 36 are illustrated. Some shallow bond pads 32 are also illustrated. The dashed lines (marked as 36) underlying one of shallow bond pad 32 indicate that these shallow bond pads may also be formed as deep bond pads, which are used in FIG. 15 to show that deep bond pads 36 may also be used as the electrical connection to integrated circuits 8.

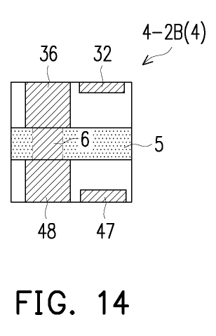

FIGS. 13 and 14 illustrate some example dummy dies 4, which are free from active devices and passive devices. FIG. 13 illustrates dummy die, with the backside features such as bond pads 46 and deep bond pads 48 shown as dashed to indicate that the dummy die 4 may be double-sided or single-sided. FIG. 14 illustrates an example double-sided dummy die 4 (also denoted as 4-2B), which includes a portion of the features as shown in FIG. 13. Through-vias 6 are shown using dashed lines to illustrate that the through-vias may be, or may not be formed. When formed, these through-vias and the overlying and underlying deep bond pads 36 and 48 may be used as electrical connections or thermal conducting paths to interconnect an overlying die and an underlying die. The bond pads 36A (FIG. 13) not connected to any through-via are used as thermal conducting channels. In accordance with some embodiments, there is a single dielectric layer 24, which is formed of a homogeneous dielectric material, on the front side of device die, and deep (dummy) bond pads 36A and 36B penetrate through the single dielectric layer 24. In accordance with alternative embodiments, there are two dielectric layers 24A and 24B on the front side of the dummy die 4, with the shallow bond pads 32 being in the upper dielectric layer 24B. On the backside of substrate 5, there may also be a single dielectric layer or two dielectric layers.

FIG. 15 illustrates package 52 formed by bonding of a plurality of tiers of device dies 4 as shown in FIGS. 10-12 and 14. In order to distinguish the device dies in package 52, each of the device dies 4 may be followed by a “-” sign and a tier number to indicate the tier of the device die. There may be “n” tiers of device dies 4 stacked, and integer n may be 2, 3, 4, 5, or more. Furthermore, in the same tier, letters A, B, C, and the like are used to distinguish the device dies 4 from each other. For example, in package 52, tier-2 device dies include active device die 4-2A and dummy dies 4-2B and 4-2C. Encapsulant 54, which may be a molding compound, a molding underfill, or the like, may be used to fill the gaps between neighboring device dies 4. The illustrated example device dies 4, besides including integrated circuits 8, may also include passive devices 33. The bonded device dies include active device dies 4-1, 4-2A, 4-3, and 4-n. Furthermore, a double-sided dummy device die 4-2B and single-sided dummy device die 4-2C are also bonded in the die stack.

In accordance with some embodiments, electrical connectors 58, which may be solder regions, metal pillars, bond pads, or the like, are formed on the top surface of the top device die 4-n. In accordance with some embodiments, the bottom device die 4-1 is free from electrical connectors at its bottom surface, and is free from through-vias therein. In each of the active device dies 4-1, 4-2A, and 4-3, there is a solid frame indicating the position of the integrated circuits 8, which also indicates which side is the front side of the corresponding device die 4. There is also a dashed frame in each of device dies 4-2A and 4-2 to represent an alternative embodiment, in which the integrated circuits 8, instead of being formed where the solid frame is, are formed wherein the dashed frame is. Accordingly, FIG. 15 has shown the face-to-face bonding, back-to-back bonding, and face-to-back bonding schemes, depending on where the integrated circuits 8 are.

In accordance with some embodiments, the bonding between the device dies 4 are through hybrid bonding, which includes the bonding of metal pads to metal pads through direct metal-to-metal bonding, and the fusion bond of the surface dielectric layers. For example, each of the deep bond pads 36 (refer to FIG. 9) and shallow bond pads 32 in one device die 4 or dummy die 4 (4-2B or 4-2C) may be bonded with any of the deep bond pads 36 and 48, and shallow bond pads 32 and 47 through metal to metal bonding. Each of the active bond pads 30 (refer to FIG. 9) may be bonded to an active bond pad 30 or 45 in another device die. The surface dielectric layer 24 (FIG. 9) may be bonded to either surface dielectric layer 24 or surface dielectric layer 44 in the neighboring die, with Si-O-Si bond being generated.

Some example bond schemes are briefly discussed as follows. It is appreciated that the front side and backside of the each of the device dies 4 may also be flipped, as aforementioned. Accordingly, the illustrate front-side bond pads may alternatively be backside bond pads, and vice versa. Bond structure 60-1 represents the bonding of a deep bond pad 36 in a first device die 4-1 to a deep bond pad 48 of a second device die 4-2A. Bond structure 60-2 represents the bonding of a deep bond pad 36 in a second device die 4-2A to a deep bond pad 36 of a third device die 4-3.

Bond structure 60-3 represents the bonding of a deep bond pad 36 in a third device die 4-3 to a shallow bond pad 32 of a second device die 4-2A. Bond structures 60-1, 60-2, and 60-3 are electrically connected to the semiconductor substrates 5 of the corresponding device dies 4. Bond structure 60-4 represents the bonding of a shallow bond pad (e.g., bond pad 32 in FIG. 10) in a third device die 4-3 to the shallow bond pad 32 of a second device die 4-2A. Bond structure 60-4 is electrically floating. Bond structures 60-5 and 60-6 represent the bonding of active bond pads (e.g., bond pads 30 and/or 45) in neighboring device dies 4, so that the integrated circuits in neighboring device dies are electrically interconnected.

Dummy dies 4-2B and 4-2C are free from active devices and passive devices, and may be used to fill the spaces left by the relatively small device die 4-2A. Dummy die 4-2B is a double-sided dummy die, with deep (dummy) bond pads on either one side or both sides of the corresponding semiconductor substrate 5. When through-via 6 is formed, the corresponding bond pads may either be dummy bond pads having no electrical function, or may be used as a signal path or power path (VDD or ground) for electrically connecting device die 4-1 to device die 4-3. For example, when a deep bond pad is formed as a part of bond structure 60-7, the corresponding deep bond pad 36 (dashed) may be used to connect to the substrate 5 of device die 4-1. When through-via 6 is not formed in dummy die 4-2B, the deep bond pads in dummy die 4-2B may be used for thermal dissipation, for example, for conducting the heat generated in device die 4-3 to device die 4-1, and then to an underlying heat sink (not shown). Shallow bond pads 32 and/or 47 may also be formed in dummy die 4-2B to improve bonding strength.

Dummy die 4-2C is a single-sided die, with deep (dummy) bond pads and shallow bond pads being formed on one side of the corresponding semiconductor substrate 5. Again, through-vias 6 may be formed in the semiconductor substrate 5, or the semiconductor substrate 5 may be free from through-vias 6.

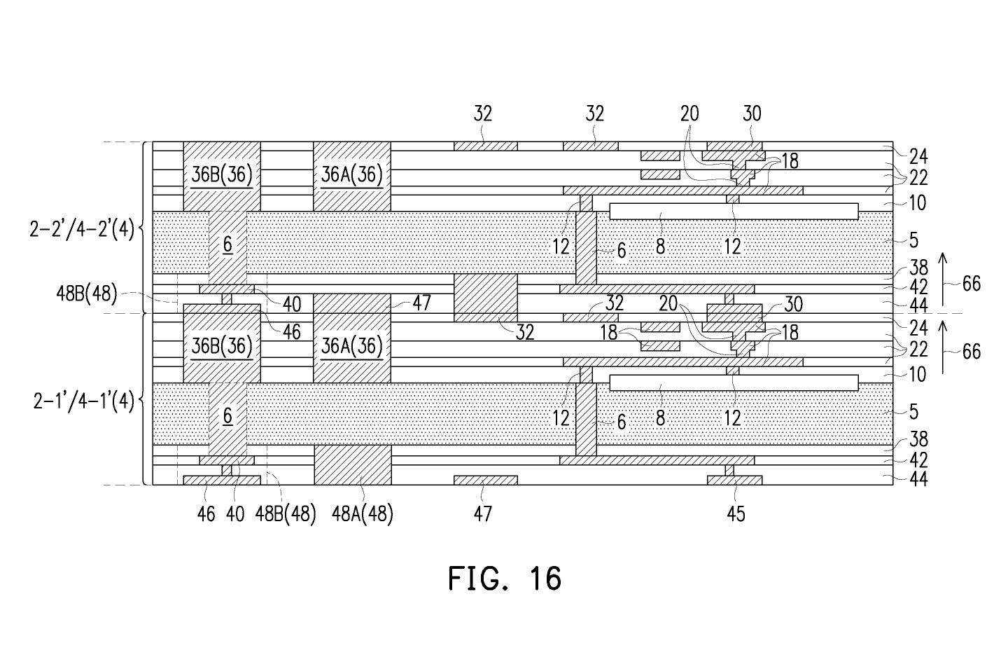

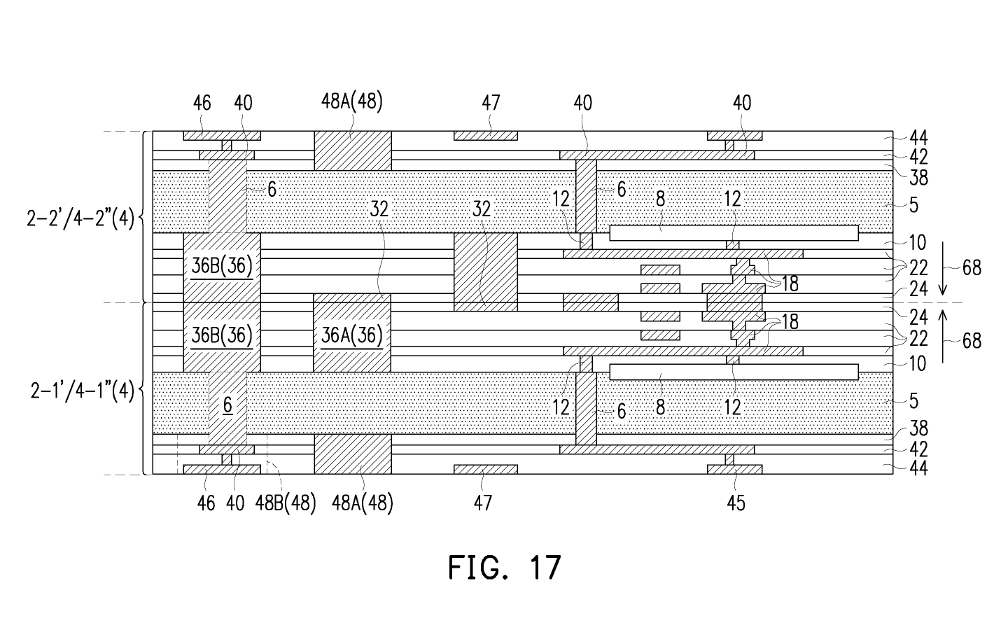

FIGS. 16 and 17 illustrate some details of two bonded dies in FIG. 15. FIG. 16 illustrates two wafers 2-1’ and 2-2’ (and/or device dies 4-1’ and 4-2’) bonded to each other through face-to-back bonding in accordance with some embodiments. Device dies 4-1’ and 4-2’ may represent two device dies (such as device dies 4-2A and 4-3) in FIG. 15. The directions of the arrows 66 indicate the directions that the front sides of the corresponding device dies 4 face. In the illustrated example, the lower device die 4-1’ has its front side bonding to the backside of upper device die 4-2’.

FIG. 17 illustrates two wafers 2-1’’ and 2-2’’ (and/or device dies 4-1’’ and 4-2’’) bonded to each other through face-to-face bonding in accordance with some embodiments. Device dies 4-1’ and 4-2’ may also represent two device dies (such as device dies 4-2A and 4-3) in FIG. 15. The directions of the arrows 68 indicate the directions that the front sides of the corresponding device dies 4 face. In the illustrated example, the lower device die 4-1’’ has its front side bonding to the backside of upper device die 4-2’’.

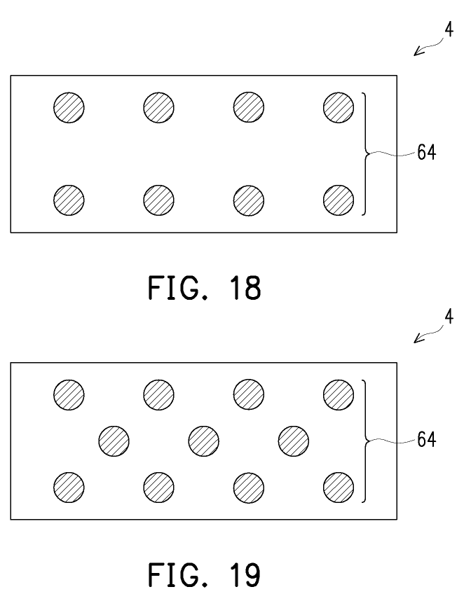

FIGS. 18-21 illustrate the top views of some bond pads 64 in accordance with some embodiments. Each of bond pads 64 may represent any of the active bond pads 30 and 45 (FIG. 9), shallow bond pads 32 and 47, bond pads 46, and deep bond pads 48. It is appreciated that although circles and rectangles are used as examples to show the top-view shapes of bond pads 64, other shapes such as hexagonal shapes, ovals, octagonal shapes, and the like, may also be adopted.

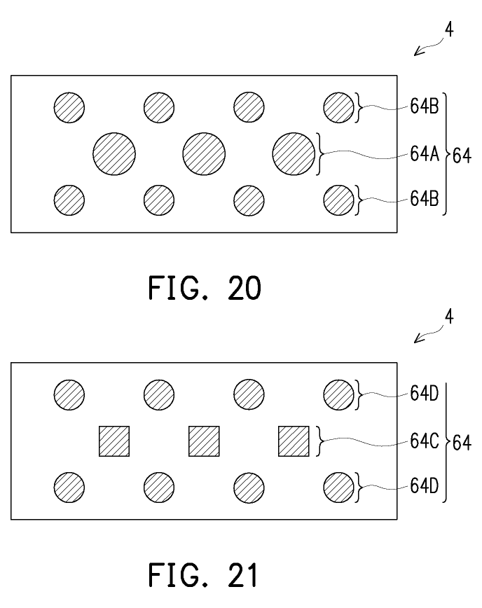

Referring to FIG. 18, the bond pads 64 may be arranged as a having a repeating pattern such as an array. The bond pads 64 may have the sizes and the shapes same as each other. Referring to FIG. 19, the bond pads 64 may be arranged as a having a staggered pattern including two arrays staggered from each other. The bond pads 64 may have the same sizes. Also, bond pads 64 may have shapes same as each other. FIG. 20 illustrates bond pads 64 arranged as being staggered, with the bond pads 64A in one array having sizes different from the sizes of the bond pads 64B in the other array. FIG. 21 illustrates bond pads 64 arranged as being staggered, with the bond pads 64C in one array having shapes different from the shapes of the bond pads 64D in the other array.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming deep bond pads, the heat dissipation from one device die to the other (and to the heat sink) is improved since the heat may be conducted through these bond pads directly to semiconductor substrate, without going through the low-heat-conducting dielectric layers. The bonding reliability is also improved due to the good anchoring of the deep bond pads to the corresponding semiconductor substrates. In addition, shallow bond pads are combined with the deep bond pads and active bond pads to further improve the bonding reliability.

In accordance with some embodiments of the present disclosure, a method comprises forming a first dielectric layer on a first wafer, wherein the first wafer comprises a first semiconductor substrate; forming a first bond pad penetrating through the first dielectric layer, wherein the first bond pad is in contact with a first surface of the first semiconductor substrate; forming a second dielectric layer on a second wafer, wherein the second wafer comprises a second semiconductor substrate; forming a second bond pad extending into the second dielectric layer; sawing the first wafer into a plurality of dies, with the first bond pad being in a first die in the plurality of dies; and bonding the first bond pad to the second bond pad.

In an embodiment, the method further comprises bonding the first dielectric layer to the second dielectric layer through fusion bonding. In an embodiment, the second bond pad physically contacts the second semiconductor substrate. In an embodiment, a first plurality of dielectric layers are formed over the first semiconductor substrate, with the first dielectric layer being a surface layer of the first plurality of dielectric layers, and wherein the first bond pad penetrates through each of the first plurality of dielectric layers. In an embodiment, the method further comprises forming integrated circuits on a front side of the first semiconductor substrate; and forming an active bond pad in the first dielectric layer, wherein the active bond pad is electrically connected to the integrated circuits.

In an embodiment, the first bond pad and the first dielectric layer are formed on the front side of the first die. In an embodiment, the first bond pad is formed on a backside of the first die, and wherein the backside is opposite to the front side. In an embodiment, the method further comprises forming a shallow bond pad in the first dielectric layer, wherein the shallow bond pad is electrically floating. In an embodiment, a second plurality of dielectric layers are formed over the second semiconductor substrate, with the second dielectric layer being a surface layer of the second plurality of dielectric layers, and wherein the second bond pad has a bottom surface contacting a top surface of an addition dielectric layer in the second plurality of dielectric layers. In an embodiment, the first wafer is free from active devices and passive devices therein.

In accordance with some embodiments of the present disclosure, a package comprises a first die comprising a first semiconductor substrate; a first dielectric layer over the first semiconductor substrate; and a first bond pad over and physically joining to the first semiconductor substrate, wherein the first bond pad extends into the first dielectric layer; and a second die over the first die, the second die comprising a second semiconductor substrate; a second dielectric layer under the first semiconductor substrate, wherein the second dielectric layer is bonded to the first dielectric layer; and a second bond pad under the second semiconductor substrate, wherein the second bond pad extends into the second dielectric layer, and the second bond pad is bonded to the first bond pad. In an embodiment, the second bond pad physically contacts the second semiconductor substrate.

In an embodiment, the second die further comprises an additional dielectric layer over and contacting the second dielectric layer, wherein the second bond pad is a shallow bond pad comprising a top surface contacting a bottom surface of the additional dielectric layer. In an embodiment, the second bond pad is fully encircled by dielectric materials. In an embodiment, the first die is a dummy die free from active devices and passive devices. In an embodiment, the first die further comprises integrated circuits on the first semiconductor substrate. In an embodiment, the package further comprises a through-via penetrating through the first semiconductor substrate, wherein the first bond pad is further in physical contact with the through-via.

In accordance with some embodiments of the present disclosure, a package comprises a first die comprising a first semiconductor substrate; integrated circuits over and on a front side of the first semiconductor substrate; a plurality of dielectric layers over and on the front side of the first semiconductor substrate; a first deep bond pad penetrating through the plurality of dielectric layers; and a first active bond pad in a first top surface layer of the first plurality of dielectric layers, wherein the first active bond pad comprises a first top surface coplanar with a second top surface of the first deep bond pad and a third top surface of the first active bond pad. In an embodiment, the package further comprises a second die over the first die, wherein the second die comprises: a second semiconductor substrate; a second deep bond pad contacting the second semiconductor substrate, wherein the second deep bond pad is bonded to and physically contacting the first deep bond pad; and a second active bond pad bonding to the first active bond pad. In an embodiment, the package further comprises a second die over the first die, wherein the second die comprises: a second semiconductor substrate; a shallow bond pad bonded to and physically contacting the first deep bond pad, wherein the shallow bond pad is physically separated from the second semiconductor substrate by at least one dielectric layer; and a second active bond pad bonding to the first active bond pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
a first die comprising:
a first semiconductor substrate;
a first plurality of dielectric layers under the first semiconductor substrate, wherein the first plurality of dielectric layers comprise a first dielectric layer as a surface layer of the first plurality of dielectric layers; and
a first bond pad comprising a continuous edge that is straight and vertical, wherein the continuous edge penetrates through the first plurality of dielectric layers, and wherein the first bond pad is in contact with a first surface of the first semiconductor substrate;
a second die under the first die, the second die comprising:
a second semiconductor substrate;
a second dielectric layer over the second semiconductor substrate; and
a second bond pad comprising at least a portion in the second dielectric layer, wherein the second bond pad is joined to the first bond pad; and
a dummy die joined to the first die, wherein the dummy die comprises:
a third semiconductor substrate; and
a conductive path penetrating through the dummy die, wherein the conductive path comprises:
a top bond pad joined to and electrically connected to the first die;
a through-via penetrating through the third semiconductor substrate; and
a bottom bond pad electrically connected to the bottom bond pad through the through-via.

2. The package of claim 1 further comprising:
integrated circuits on a front side of the first semiconductor substrate; and
an active bond pad in the first dielectric layer, wherein the active bond pad is electrically connected to the integrated circuits.

3. The package of claim 2, wherein the first bond pad is formed on a backside of the first die, and wherein the backside is opposite to the front side.

4. The package of claim 1 further comprising:
a shallow bond pad in the first dielectric layer, wherein the shallow bond pad is electrically floating.

5. The package of claim 1, wherein the second die further comprises a second plurality of dielectric layers over the second semiconductor substrate, with the second dielectric layer being a surface layer of the second plurality of dielectric layers.

6. The package of claim 5, wherein the second bond pad has a bottom surface contacting a top surface of an additional dielectric layer in the second plurality of dielectric layers.

7. The package of claim 1, wherein the dummy die free from active devices and passive devices therein.

8. The package of claim 1, wherein the top bond pad extends from a top surface of the third semiconductor substrate to a topmost surface of the dummy die.

9. The package of claim 8, wherein the bottom bond pad extends from a bottom surface of the third semiconductor substrate to a bottommost surface of the dummy die.

10. A package comprising:
a first die comprising:
a first semiconductor substrate;
a first dielectric layer over the first semiconductor substrate; and
a first bond pad over and physically joining to the first semiconductor substrate, wherein the first bond pad extends into the first dielectric layer; and
a second die over the first die, the second die comprising:
a second semiconductor substrate;
a second dielectric layer under the first semiconductor substrate, wherein the second dielectric layer is bonded to the first dielectric layer; and
a second bond pad under the second semiconductor substrate, wherein the second bond pad extends into the second dielectric layer, and the second bond pad is bonded to the first bond pad.

11. The package of claim 10, wherein the second bond pad physically contacts the second semiconductor substrate.

12. The package of claim 10, wherein the second die further comprises an additional dielectric layer over and contacting the second dielectric layer, wherein the second bond pad is a shallow bond pad comprising a top surface contacting a bottom surface of the additional dielectric layer.

13. The package of claim 10, wherein the second bond pad is fully encircled by dielectric materials.

14. The package of claim 10 further comprising a dummy die over joined to the first die, wherein the dummy die comprises:
a third semiconductor substrate; and
a conductive path penetrating through the dummy die, wherein the conductive path comprises:
a third bond pad joined to and electrically connected to the first die;
a through-via penetrating through the third semiconductor substrate; and
a fourth bond pad on an opposite side of the dummy die than the third bond pad, wherein the third bond pad is electrically connected to the fourth bond pad through the through-via.

15. The package of claim 10, wherein the first die further comprises integrated circuits on the first semiconductor substrate.

16. The package of claim 10 further comprising a through-via penetrating through the first semiconductor substrate, wherein the first bond pad is further in physical contact with the through-via.

17. A package comprising:
a first die comprising:
a first semiconductor substrate;
integrated circuits over and on a front side of the first semiconductor substrate;
a plurality of dielectric layers over and on the front side of the first semiconductor substrate;
a first deep bond pad penetrating through the plurality of dielectric layers; and
a first active bond pad in a first top surface layer of the plurality of dielectric layers, wherein the first active bond pad comprises a first top surface coplanar with a second top surface of the first deep bond pad and a third top surface of the first active bond pad.

18. The package of claim 17 further comprising a second die over the first die, wherein the second die comprises:
a second semiconductor substrate;
a second deep bond pad contacting the second semiconductor substrate, wherein the second deep bond pad is bonded to and physically contacting the first deep bond pad; and
a second active bond bonding to the first active bond pad.

19. The package of claim 17 further comprising a dummy die over and joined to the first die, wherein the dummy die comprises:
an additional semiconductor substrate; and
a conductive path penetrating through the dummy die, wherein the conductive path comprises:
a bottom bond pad under the additional semiconductor substrate, the bottom bond pad joined to and electrically connected to the first die;
a through-via penetrating through the additional semiconductor substrate; and
a top bond pad electrically connected to the bottom bond pad through the through-via.

20. The package of claim 19, wherein the top bond pad and the bottom bond pad are in contact with a top surface and a bottom surface, respectively, of the additional semiconductor substrate.
